(19) United States
(12) Patent Application Publication
(10) Pub. No.: US 2026/0098918 A1
(43) Pub. Date: Apr. 9, 2026

(54) SPIN HALL MAGNETIC SENSOR

(71) Applicants: HYUNDAI MOTOR COMPANY, Seoul (KR); KIA CORPORATION, Seoul (KR); KOREA INSTITUTE OF SCIENCE AND TECHNOLOGY, Seoul (KR)

(72) Inventors: Joon-Hyun KWON, Hwaseong-si (KR); Sang-Hyeok YANG, Hwaseong-si (KR); Su-Jung NOH, Hwaseong-si (KR); Young-Chan KIM, Hwaseong-si (KR); Han-Saem LEE, Hwaseong-si (KR); Ji-Sung LEE, Hwaseong-si (KR); Byoung-Chul MIN, Seoul (KR); Jong-Bum CHOI, Seoul (KR); Dong-Soo HAN, Seoul (KR)

(21) Appl. No.: 19/060,079

(22) Filed: Feb. 21, 2025

(30) Foreign Application Priority Data
Oct. 8, 2024 (KR) 10-2024-0136635

(51) Int. Cl. G01R 33/07; H10N 52/85

(52) U.S. Cl. CPC G01R 33/075; H10N 52/85

(57) ABSTRACT

A spin Hall magnetic sensor includes a plurality of magnetic thin film bodies each including a magnetic layer stacked on a non-magnetic layer, and a plurality of non-magnetic bodies disposed between the plurality of magnetic thin film bodies. The plurality of magnetic thin film bodies include a first magnetic thin film body, a second magnetic thin film body disposed axially symmetrically to the first magnetic thin film body with respect to a first axis, a third magnetic thin film body disposed axially symmetrically to the second magnetic thin film body with respect to a second axis orthogonal to the first axis, and a fourth magnetic thin film body disposed axially symmetrically to the third magnetic thin film body with respect to the first axis.

### CROSS-REFERENCE TO RELATED APPLICATION

This application claims priority to Korean Patent Application No. 10-2024-0136635, filed on Oct. 8, 2024, the disclosures of which are incorporated herein by reference in their entirety.

### TECHNICAL FIELD

The present disclosure relates to a magnetic sensor using the spin Hall effect.

### BACKGROUND

A multilayer magnetic thin film structure may include a non-magnetic layer/magnetic layer/non-magnetic layer, where a charge current is injected from the outside of the multilayer magnetic thin film structure, a spin current may be generated in the non-magnetic layer by the spin Hall effect, and the spin current is transmitted to an adjacent magnetic layer to generate a spin orbit torque (SOT).

For instance, a Wheatstone bridge structure may be used in magnetic sensors to detect a change in a minute resistance and improve signal sensitivity.

In some cases, when an angle α of a unit structure of the Wheatstone bridge structure varies, it may be possible to measure a magnetic Hall resistance R_{xy} as well as a magnetic resistance Rₓₓ in an x-y plane.

### SUMMARY

The present disclosure describes a magnetic sensor that is improved by a Wheatstone bridge structure to observe magnetic Hall resistance generated by a spin orbit torque (SOT).

According to one aspect of the present disclosure, a spin Hall magnetic sensor includes a plurality of magnetic film bodies, where each of the plurality of magnetic film bodies includes a magnetic layer stacked on a non-magnetic layer, and a plurality of non-magnetic bodies disposed between the plurality of magnetic film bodies. The plurality of magnetic film bodies include a first magnetic film body, a second magnetic film body disposed axially symmetrically to the first magnetic film body with respect to a first axis in a plane, a third magnetic film body disposed axially symmetrically to the second magnetic film body with respect to a second axis orthogonal to the first axis in the plane, and a fourth magnetic film body disposed axially symmetrically to the third magnetic film body with respect to the first axis in the plane.

Implementations according to this aspect can include one or more of the following features. For example, each of the plurality of magnetic film bodies can be configured to, in response to a current provided to a corresponding one of the plurality of magnetic film bodies, generate (i) a spin current in the non-magnetic layer of the corresponding magnetic film body and (ii) a spin orbit torque (SOT) in the magnetic layer of the corresponding magnetic film body. In some examples, the plurality of non-magnetic bodies include a first non-magnetic body that connects the first magnetic film body with the second magnetic film body, a second non-magnetic body that connects the second magnetic film body with the third magnetic film body, a third non-magnetic body that connects the third magnetic film body with the fourth magnetic film body, and a fourth non-magnetic body that connects the fourth magnetic film body with the first magnetic film body.

In some implementations, the plurality of non-magnetic bodies can have (i) a metal alloy structure configured to generate an SOT or (ii) a superlattice structure. In some examples, each of the plurality of magnetic film bodies has three or more bodies that connected to one another. In some examples, each of the plurality of magnetic film bodies includes a first body having a first end that is connected to one of the plurality of non-magnetic bodies, where the first body extends in a longitudinal direction that defines a preset angle with respect to an input direction of the current provided to the corresponding magnetic film body, a second body disposed parallel to the first body; and a first connector that connects a second end of the first body to an end of the second body. In some implementations, each of the first body, the second body, and the first connector includes the magnetic layer.

In some implementations, the preset angle defined between the longitudinal direction of the first body and the input direction of the current is greater than 0° and less than 90°. For instance, the preset angle defined between the longitudinal direction of the first body and the input direction of the current is in a range of 45°±5°. In some implementations, a longitudinal direction of the first connector defines an angle of 90°±5° with the input direction of the current.

In some implementations, each of the plurality of magnetic film bodies is bent a plurality of times. For example, each of the plurality of magnetic film bodies includes a first body having a first end that is connected to a corresponding one of the plurality of non-magnetic bodies, where the first body extends in a first direction that defines a preset angle with respect to an input direction of a current provided to the corresponding magnetic film body, a first bridge that is bent from a second end of the first body and extends in a second direction, the first bridge having a first end connected to the second end of the first body, and a second body that is bent from a second end of the first bridge and extends parallel to the first body in the first direction, the second body having a first end connected to a second end of the first bridge.

In some implementations, each of the plurality of magnetic film bodies further includes a second bridge that is bent from a second end of the second body and extends in the second direction parallel to the first bridge, the second bridge having a first end connected to the second end of the second body, and a third body that is bent from a second end of the second bridge, extends parallel to the second body in the first direction, and connected to another of the plurality of non-magnetic bodies.

In some implementations, the preset angle defined between the first direction of the first body and the input direction of the current is greater than 0° and less than 90°. For instance, the preset angle is in a range of 45°±5°. In some implementations, the second direction of the first bridge defines an angle of 90°±5° with the input direction of the current.

In some implementations, a sensitivity of the spin Hall magnetic sensor is defined by (i) the preset angle and (ii) a number of the plurality of times in which each of the plurality of magnetic film bodies is bent..

According to the spin Hall magnetic sensor and the method of measuring magnetic resistance using the same according to the present disclosure, it can be possible to increase the sensor output voltage and sensitivity. In addition, it can be possible to increase sensitivity as the number of bridges increases. In some examples, even when the number of contact points increases, a structure in which patterns can be easily arranged during patterning can be implemented.

### BRIEF DESCRIPTION OF THE DRAWINGS

FIG. 1 is a schematic view showing an example of a spin Hall magnetic sensor.

FIG. 2 is a schematic view showing an example of a spin Hall magnetic sensor.

FIGS. 3 and 4 are views showing an example of a sensor structure in which anisotropic magnetic resistance can be measured.

FIG. 5 is a schematic view showing an example of a spin Hall magnetic sensor.

FIG. 6 shows an example result of measuring a signal sensitivity of the sensors of FIGS. 2 and 5.

### DETAILED DESCRIPTION

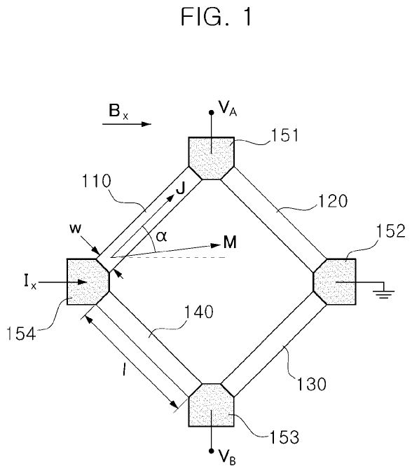

FIG. 1 is a view schematically illustrating an example of a spin Hall magnetic sensor. Hereinafter, a spin Hall magnetic sensor according to the present disclosure will be described with reference to FIG. 1.

The spin Hall magnetic sensor can function as a magnetic sensor with high sensitivity, which uses the spin Hall effect by a multilayered magnetic thin film structure, is formed in a Wheatstone bridge structure to measure magnetic Hall resistance through an angle configuration of a body, and uses only a magnetic resistance component generated by a spin orbit torque (SOT).

In some implementations, the spin Hall magnetic sensor 100 is configured to include a plurality of magnetic thin film bodies 110, 120, 130, and 140 and a plurality of non-magnetic bodies 151, 152, 153, and 154.

The plurality of magnetic thin film bodies can include a first magnetic thin film body 110 having a longitudinal direction forming a constant angle with a direction of an input current Iₓ, a second magnetic thin film body 120 having a longitudinal direction disposed to form a constant angle with the longitudinal direction of the first magnetic thin film body 110, a third magnetic thin film body 130 having a longitudinal direction disposed to form a constant angle with the longitudinal direction of the second magnetic thin film body 120 and disposed parallel to the first magnetic thin film body 110, and a fourth magnetic thin film body 140 having a longitudinal direction disposed to form a constant angle with the longitudinal direction of the third magnetic thin film body 130 and disposed parallel to the second magnetic thin film body 120.

In addition, the plurality of non-magnetic bodies can include a first non-magnetic body 151 connecting the first magnetic thin film body 110 with the second magnetic thin film body 120, a second non-magnetic body 152 connecting the second magnetic thin film body 120 and the third magnetic thin film body 130, a third non-magnetic body 153 connecting the third magnetic thin film body 130 with the fourth magnetic thin film body 140, and a fourth non-magnetic body 154 connecting the fourth magnetic thin film body 140 with the first magnetic thin film body 110.

That is, the non-magnetic body is disposed at a node between the magnetic thin film bodies.

In some implementations, the non-magnetic body can have a metal alloy in which the SOT is generated or a superlattice structure.

In some examples, the magnetic thin film body has a multilayer magnetic thin film structure in which a non-magnetic layer/magnetic layer/non-magnetic layer are sequentially stacked, and when a charge current is injected from the outside, a spin current is generated in the non-magnetic layer by the spin Hall effect, and the spin current is transmitted to an adjacent magnetic layer to generate the SOT.

The magnetic thin film body having the three-layer structure can have, for example, a Pt/Co/Ta structure.

In the present disclosure, in the Wheatstone bridge structure including the above-described magnetic thin film body, an AC current Iₓ can be applied through a node between the first magnetic thin film body 110 and the fourth magnetic thin film body 140, and a voltage |V_{A}-V_{B}| between a node between the first magnetic thin film body 110 and the second magnetic thin film body 120 and a node between the third magnetic thin film body 130 and the fourth magnetic thin film body 140 can be measured.

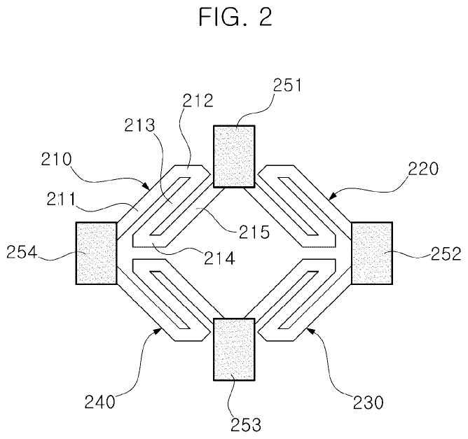

FIG. 2 is a schematic view showing an example of a spin Hall magnetic sensor.

The spin Hall magnetic sensor in FIG. 2 is configured to include a plurality of magnetic thin film bodies 210, 220, 230, and 240 and a plurality of non-magnetic bodies 251, 252, 253, and 254.

The plurality of magnetic thin film bodies can include a first magnetic thin film body 210, a second magnetic thin film body 220 having a longitudinal direction disposed to form a constant angle with the longitudinal direction of the first magnetic thin film body 210, a third magnetic thin film body 230 having a longitudinal direction disposed to form a constant angle with the longitudinal direction of the second magnetic thin film body 220 and disposed parallel to the first magnetic thin film body 210, and a fourth magnetic thin film body 240 having a longitudinal direction disposed to form a constant angle with the longitudinal direction of the third magnetic thin film body 230 and disposed parallel to the second magnetic thin film body 220.

In addition, the plurality of non-magnetic bodies can include a first non-magnetic body 251 connecting the first magnetic thin film body 210 with the second magnetic thin film body 220, a second non-magnetic body 252 connecting the second magnetic thin film body 220 and the third magnetic thin film body 230, a third non-magnetic body 253 connecting the third magnetic thin film body 230 with the fourth magnetic thin film body 240, and a fourth non-magnetic body 254 connecting the fourth magnetic thin film body 240 with the first magnetic thin film body 210. That is, the non-magnetic body is disposed at a node between the magnetic thin film bodies.

Furthermore, the magnetic thin film body of the spin Hall magnetic sensor in FIG. 2 can be configured in a zig-zag shape and configured to improve an output signal by varying the number of times of repetitions N of the corresponding structure.

For instance, the first magnetic thin film body 210 can include a first body 211, a first connector 212, a second body 213, a second connector 214, and a third body 215, and the connectors and the bodies can be further repeated several times.

The first body 211, the second body 213, and the third body 215 are formed parallel to the longitudinal direction of the first magnetic thin film body 210, the first connector 212 is connected to the first body 211 and one end of the second body 213, and the second connector 214 is connected between the other end of the second body 213 and the third body 215.

In addition, the magnetic film unit can have a multilayered magnetic film structure in which a non-magnetic layer/magnetic layer/non-magnetic layer are sequentially stacked.

In addition, in particular, unlike the unit structure of the Wheatstone bridge used as the magnetic sensor generally made of only a magnetic material, the unit structure of the Wheatstone bridge can be implemented to have a structure in which a direction of a current flowing through the magnetic material can be constantly fixed at all times by inserting a non-magnetic material into the magnetic materials (e.g., the first connector 212, the second body 213, and the second connector 214 are made of a non-magnetic material).

Hall resistance increase/decrease components due to the SOT depends on the direction of the current.

When the first body 211, the second body 213, and the third body 215 of the body of the Wheatstone bridge structure are all made of a magnetic material, for example, the effects caused by currents flowing at angles α of the bridge of +45 degrees and −135 degrees based on a +x direction are mutually canceled, thereby canceling all the Hall resistances (Hall voltages) generated by the SOT.

On the other hand, when the second body 213 is formed of a non-magnet and inserted into the middle of the Wheatstone bridge structure to fix the direction of the current flowing through the magnetic layer, the Hall resistance (output Hall voltage) by the SOT increases in proportion to the number (N) of structures. Here, the first connector 212 and the second connector 214 can also be non-magnets. That is, three or more bodies can be formed, and when the number of bodies is 2n+1 (n is a natural number), n bodies can be formed of a non-magnet.

Therefore, when one bridge of a portion in which currents are canceled is made of a non-magnetic material, the effect of increasing the output voltage and sensitivity can be induced. In addition, the more the number of bridges, the more sensitivity.

In addition, as the non-magnetic material, a material usable as a general electrode such as Au or Cu can be used.

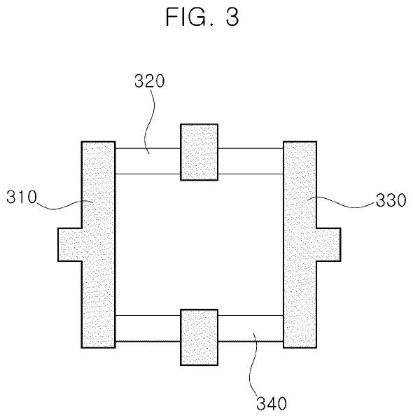

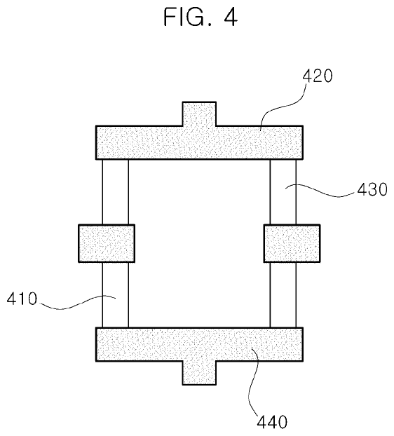

Additionally, FIGS. 3 and 4 show a structure in which the AMR, which is the magnetic resistance effect that varies depending on a magnetic field and an angle of a current, can be measured when a bridge angle of the Wheatstone bridge is 0 or 90 degrees, and such a structure can be used as an element for detecting another output signal.

FIG. 3 is a case in which the angle of the bridge is 0 degrees.

That is, the sensor structure has a structure in which longitudinal directions of the magnetic thin film bodies 320 and 340 are disposed in a direction parallel to the direction of the applied current, non-magnetic bodies 310 and 330 are parallel to each other, and both ends of the magnetic thin film bodies 320 and 340 are disposed to be connected to each other.

In addition, FIG. 4 is a case in which the angle of the bridge is 90 degrees.

That is, the sensor structure is a structure in which longitudinal directions of the magnetic thin film bodies 410 and 430 are disposed in a direction perpendicular to the direction of the applied current, non-magnetic bodies 420 and 440 are parallel to each other, and both ends of the magnetic thin film bodies 410 and 430 are disposed to be connected to each other.

In both cases, the magnetic resistive effect rather than the Hall effect can be observed. Therefore, the bridge angle is preferably 0 degrees<α<90 degrees.

Furthermore, the Hall resistance to be observed in the present disclosure has the largest output at an angle of 45°±5° and has a structure in which the magnetic resistance effect can be canceled or minimized.

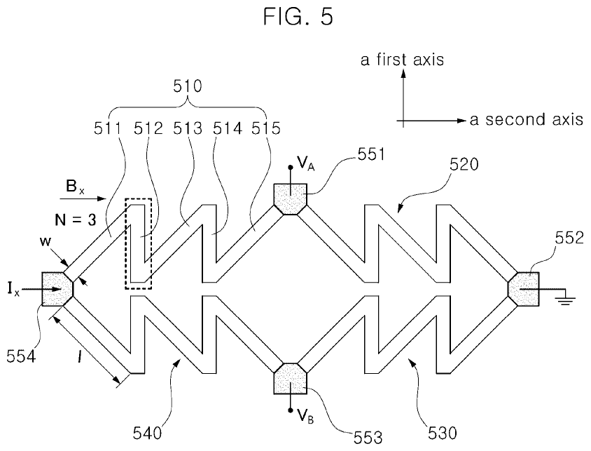

FIG. 5 is a schematic view showing an example of a spin Hall magnetic sensor.

The spin Hall magnetic sensor in FIG. 5, for instance, includes a plurality of magnetic thin film bodies 510, 520, 530, and 540 and a plurality of non-magnetic bodies 551, 552, 553, and 554.

The plurality of magnetic film bodies can include a first magnetic thin film body 510, a second magnetic thin film body 520 disposed axially symmetrically to the first magnetic thin film body 510 with respect to a first axis in a plan view, a third magnetic thin film body 530 disposed axially symmetrically to the second magnetic thin film body 520 with respect to a second axis orthogonal to the first axis in a plan view and point-symmetrically to the first magnetic thin film body 510, and a fourth magnetic thin film body 540 disposed axially symmetrically to the third magnetic thin film body 530 based on the first axis in a plan view and point-symmetrically to the second magnetic thin film body 520.

In addition, the plurality of non-magnetic bodies can include a first non-magnetic body 551 connecting the first magnetic thin film body 510 with the second magnetic thin film body 520, a second non-magnetic body 552 connecting the second magnetic thin film body 520 and the third magnetic thin film body 530, a third non-magnetic body 553 connecting the third magnetic thin film body 530 with the fourth magnetic thin film body 540, and a fourth non-magnetic body 554 connecting the fourth magnetic thin film body 540 with the first magnetic thin film body 510. That is, the non-magnetic body is disposed at a node between the magnetic thin film bodies.

Furthermore, the magnetic thin film body of the spin Hall magnetic sensor of FIG. 5 can be formed in a zig-zag shape and formed to improve an output signal by changing the number of times of repetitions N (e.g., N=3) of the corresponding structure.

For instance, the first magnetic thin film body 510 can include a first body 511, a first connector 512, a second body 513, a second connector 514, and a third body 515, and the connectors and the bodies can be further repeated several times.

The first body 511, the second body 513, and the third body 515 have the longitudinal direction formed at a constant angle with the direction of the input current Iₓ, the first connector 512 is connected to the first body 511 and one end portion of the second body 513, and the second connector 514 is connected between the other end portion of the second body 513 and the third body 515.

In particular, the first connector 512 and the second connector 514 preferably have the longitudinal direction close to the direction perpendicular to the direction of the input current Iₓ.

In addition, the bodies 511, 513, and 515 and the connectors 512 and 514 of the magnetic film body can have a multilayered magnetic film structure in which a non-magnetic layer/magnetic layer/non-magnetic layer are sequentially stacked.

In some implementations, referring to FIG. 5, a magnet connecting bridge (marked by dotted lines) of a component perpendicular to a surface direction of an external magnetic field Bₓ functions as only a current passage without being involved in the generation of signals (without the Hall effect) and has a structure in which as the number of bridges tilted at a predetermined angle by the current or the external magnetic field increases, the output signal and sensitivity can be improved. The magnet connecting bridge can refer to, for example, the connectors 512 and 514 in FIG. 5 and the other symmetrically arranged connected between other non-magnetic bodies.

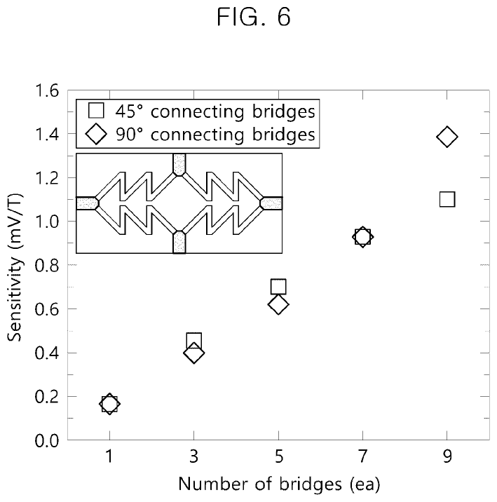

FIG. 6 shows that a change in sensitivity according to the increase in number of bridges in the sensors shown in FIGS. 2 and 5 is measured, as the number of bridges increases, sensitivity increases almost similarly, and in the case of nine bridges, it can be confirmed that higher sensitivity appears in the sensor in FIG. 5.

In addition, in terms of the overall structure, since only a horizontal length increases, in a state in which the magnetic layer structure is connected, the above structure is a structure in which patterns can be easily arranged during patterning.

In the sensor shown in FIG. 2, since electrodes are added identically as much as added multi-segments, in this case, the number of contact points between the bridge structure including the magnet and the non-magnetic material continuously increases.

As the number of contact points increases, contact resistance increases, which increases the resistance of the overall element, and the increased resistance can become noise or exceed the limits of the measurement range, making measurement difficult.

In addition, in the sensor in FIG. 2, since the number of contact points is large, while the difficulty of alignment with each contact point can be high during a photolithography process for forming the pattern, in the sensor in FIG. 5, even when the number of bridges increases, alignment needs to be performed on only four electrodes, and thus alignment between patterns is easy during patterning.

Although the present disclosure has been described above with reference to the exemplary drawings, the present disclosure is not limited to the described implementations, and it is apparent to those skilled in the art that various modifications and changes can be made without departing from the spirit and scope of the present disclosure. Therefore, these modified examples or changed examples should be included in the claims of the present disclosure, and the scope of the present disclosure should be construed based on the appended claims.

What is claimed is:

1. A spin Hall magnetic sensor comprising:
a plurality of magnetic film bodies, each of the plurality of magnetic film bodies comprising a magnetic layer stacked on a non-magnetic layer; and
a plurality of non-magnetic bodies disposed between the plurality of magnetic film bodies,
wherein the plurality of magnetic film bodies comprise:
a first magnetic film body,
a second magnetic film body disposed axially symmetrically to the first magnetic film body with respect to a first axis in a plane,
a third magnetic film body disposed axially symmetrically to the second magnetic film body with respect to a second axis orthogonal to the first axis in the plane, and
a fourth magnetic film body disposed axially symmetrically to the third magnetic film body with respect to the first axis in the plane.

2. The spin Hall magnetic sensor of claim 1, wherein each of the plurality of magnetic film bodies is configured to, in response to a current provided to a corresponding one of the plurality of magnetic film bodies, generate (i) a spin current in the non-magnetic layer of the corresponding magnetic film body and (ii) a spin orbit torque (SOT) in the magnetic layer of the corresponding magnetic film body.

3. The spin Hall magnetic sensor of claim 2, wherein the plurality of non-magnetic bodies comprise:
a first non-magnetic body that connects the first magnetic film body with the second magnetic film body;
a second non-magnetic body that connects the second magnetic film body with the third magnetic film body;
a third non-magnetic body that connects the third magnetic film body with the fourth magnetic film body; and
a fourth non-magnetic body that connects the fourth magnetic film body with the first magnetic film body.

4. The spin Hall magnetic sensor of claim 3, wherein the plurality of non-magnetic bodies have (i) a metal alloy structure configured to generate an SOT or (ii) a superlattice structure.

5. The spin Hall magnetic sensor of claim 3, wherein each of the plurality of magnetic film bodies has three or more bodies that connected to one another.

6. The spin Hall magnetic sensor of claim 3, wherein each of the plurality of magnetic film bodies comprises:
a first body having a first end that is connected to one of the plurality of non-magnetic bodies, the first body extending in a longitudinal direction that defines a preset angle with respect to an input direction of the current provided to the corresponding magnetic film body;
a second body disposed parallel to the first body; and
a first connector that connects a second end of the first body to an end of the second body.

7. The spin Hall magnetic sensor of claim 6, wherein each of the first body, the second body, and the first connector comprises the magnetic layer.

8. The spin Hall magnetic sensor of claim 6, wherein the preset angle defined between the longitudinal direction of the first body and the input direction of the current is greater than 0° and less than 90°.

9. The spin Hall magnetic sensor of claim 6, wherein the preset angle defined between the longitudinal direction of the first body and the input direction of the current is in a range of 45°±5°.

10. The spin Hall magnetic sensor of claim 6, wherein a longitudinal direction of the first connector defines an angle of 90°±5° with the input direction of the current.

11. The spin Hall magnetic sensor of claim 1, wherein each of the plurality of magnetic film bodies is bent a plurality of times.

12. The spin Hall magnetic sensor of claim 11, wherein each of the plurality of magnetic film bodies comprises:
a first body having a first end that is connected to a corresponding one of the plurality of non-magnetic bodies, the first body extending in a first direction that defines a preset angle with respect to an input direction of a current provided to the corresponding magnetic film body;
a first bridge that is bent from a second end of the first body and extends in a second direction, the first bridge having a first end connected to the second end of the first body; and
a second body that is bent from a second end of the first bridge and extends parallel to the first body in the first direction, the second body having a first end connected to a second end of the first bridge.

13. The spin Hall magnetic sensor of claim 12, wherein each of the plurality of magnetic film bodies further comprises:
a second bridge that is bent from a second end of the second body and extends in the second direction parallel to the first bridge, the second bridge having a first end connected to the second end of the second body; and
a third body that is bent from a second end of the second bridge, extends parallel to the second body in the first direction, and connected to another of the plurality of non-magnetic bodies.

14. The spin Hall magnetic sensor of claim 12, wherein the preset angle defined between the first direction of the first body and the input direction of the current is greater than 0° and less than 90°.

15. The spin Hall magnetic sensor of claim 12, wherein the preset angle defined between the first direction of the first body and the input direction of the current is in a range of 45°±5°.

16. The spin Hall magnetic sensor of claim 12, wherein the second direction of the first bridge defines an angle of 90°±5° with the input direction of the current.

17. The spin Hall magnetic sensor of claim 12, wherein a sensitivity of the spin Hall magnetic sensor is defined by (i) the preset angle and (ii) a number of the plurality of times in which each of the plurality of magnetic film bodies is bent.
